(19) United States
(12) Patent Application Publication
(10) Pub. No.: US 2025/0087975 A1
(43) Pub. Date: Mar. 13, 2025

(54) POWER EQUIPMENT AND ASSEMBLING METHOD THEREOF

(71) Applicant: Delta Electronics (Shanghai) Co., Ltd., Shanghai (CN)

(72) Inventors: Yansong Lu, Shanghai (CN); Jun Chen, Shanghai (CN); Xiaofei Wei, Shanghai (CN); Wei Wang, Shanghai (CN)

(21) Appl. No.: 18/825,030

(22) Filed: Sep. 5, 2024

(30) Foreign Application Priority Data
Sep. 7, 2023 (CN) 202311156948.1

(51) Int. Cl. H02B 1/30

(52) U.S. Cl. CPC H02B 1/306

(57) ABSTRACT

A power equipment and an assembling method thereof are disclosed. The power equipment includes an installation cabinet, a plurality of power modules and at least one expansion power module. The installation cabinet includes a top and two lateral sides. The plurality of power modules are electrically connected to the installation cabinet and arranged in an array on the top of the installation cabinet. The plurality of power modules and the installation cabinet are assembled as one main body. The main body and the expansion power module are transported to an installation site, respectively. The at least one expansion power module is detachably disposed on one of the two lateral sides of the installation cabinet and electrically connected to the installation cabinet through the expansion cables reserved in the installation cabinet.

### CROSS-REFERENCE TO RELATED APPLICATION

This application claims priority to China Patent Application No. 202311156948.1, filed on Sep. 7, 2023. The entire contents of the above-mentioned patent application are incorporated herein by reference for all purposes.

### FIELD OF THE INVENTION

The present disclosure relates to a power equipment, and more particularly to a power equipment capable of quickly expanding power modules at installation site and an assembling method thereof.

### BACKGROUND OF THE INVENTION

As the energy demand continues to develop, the requirements for output power of the power equipment are increased. A conventional power equipment includes a plurality of power modules and an installation cabinet. The plurality of power modules are installed in an accommodation portion of the installation cabinet to form one main body. However, the conventional power equipment has a fixed number of power modules. The power module cannot be expanded at the installation site. It is also impossible to increase the output power of the power equipment.

A general standard container has a fixed size and it usually allows to accommodate two main bodies for transportation. However, if an additional power module is installed outside the main body in advance for increasing the output power of the power equipment, it will result in an increase in the overall size of the power equipment, and the standard container for transportation can only accommodate one main body with additional power modules. It reduces the transportation efficiency and wastes the transportation resources.

On the other hand, the power modules in the conventional power equipment have a modular structure, but are limited in the size of the main body and the installation method thereof. It is unable to adjust the layout according to the requirements.

Therefore, there is a need of providing a power equipment capable of quickly expanding power modules at installation site and an assembling method thereof, to obviate the drawbacks encountered by the prior arts.

### SUMMARY OF THE INVENTION

An object of the present disclosure is to provide a power equipment and an assembling method thereof for achieving the effects of expanding the power modules, increasing the output power, improving the transportation efficiency and saving the transportation resources.

An object of the present disclosure is to provide a power equipment including an installation cabinet, a plurality of power modules and at least one expansion power module. The installation cabinet includes a top and two lateral sides. The plurality of power modules are electrically connected to the installation cabinet and arranged in an array on the top of the installation cabinet. The at least one expansion power module is detachably disposed on one of the two lateral sides of the installation cabinet and electrically connected to the installation cabinet.

In an embodiment, the installation cabinet and the plurality of power modules are assembled as a first main body for transportation, and the expansion power module is as a second main body for transportation.

In an embodiment, the power equipment further includes an installation bracket detachably disposed on one of the two lateral sides of the installation cabinet. The installation bracket includes a guiding rail, the guiding rail includes a slot disposed at a first end thereof and at least one fixing hole disposed at a second end thereof. The expansion power module is slid from the second end of the guiding rail toward the first end, and locked in the slot, and then the expansion power module is fixed to the at least one fixing hole.

In an embodiment, the installation cabinet includes a set of expansion interfaces arranged on one of the two lateral sides of the installation cabinet, and the set of expansion interfaces and the expansion power module are located on an identical one of the two lateral sides of the installation cabinet.

In an embodiment, a plurality of expansion cables are reserved in the installation cabinet for electrically connecting the expansion power module.

In an embodiment, the set of expansion interfaces includes a first expansion interface, a second expansion interface and a third expansion interface; and the installation cabinet includes a DC warehouse, an AC warehouse and a wiring warehouse. The DC warehouse is located adjacent to the AC warehouse, and the wiring warehouse is in communication with and installed on tops of the DC warehouse and the AC warehouse.

In an embodiment, the DC warehouse includes a set of expansion DC bus bars and a set of expansion DC cables disposed therein. The set of expansion DC cables includes a first end electrically connected to the set of expansion DC bus bars, and a second end reserved in the wiring warehouse. The second end of the set of expansion DC cables passes through the first expansion interface of the set of expansion interfaces and is electrically connected to a DC side of the expansion power module.

In an embodiment, the AC warehouse includes a set of expansion AC terminals and a set of expansion AC cables disposed therein. The set of expansion AC cables includes a first end electrically connected to the set of expansion AC terminals, and a second end reserved in the wiring warehouse. The second end of the set of expansion AC cables passes through the second expansion interface of the set of expansion interfaces and is electrically connected to a AC side of the expansion power module.

In an embodiment, the AC warehouse includes a control box and a set of expansion control cables disposed therein. The set of expansion control cables includes a first end electrically connected to the control box, and a second end reserved in the wiring warehouse. The second end of the set of expansion control cables passes through the third expansion interface of the set of expansion interfaces and is electrically connected to a control board of the expansion power module.

In an embodiment, the plurality of power modules form a first array and are installed on the top of the installation cabinet. The installation cabinet further includes a plural sets of interfaces, and each of the plural sets of interfaces is disposed on a front side of the installation cabinet and spatially corresponding to one of the power modules in the first array.

In an embodiment, at least part of the plurality of power modules form a first array and are installed on a front side of the top of the installation cabinet. The installation cabinet includes a plural sets of interfaces, and each of the plural sets of interfaces is disposed on a front side of the installation cabinet and spatially corresponding to one of the power modules in the first array. At least part of the remaining plurality of power modules form a second array and are installed on a rear side of the top of the installation cabinet. The installation cabinet further includes a plural sets of interfaces, and each of the plural sets of interfaces is disposed on a rear side of the installation cabinet and spatially corresponding to one of the power modules in the second array.

In an embodiment, the power equipment includes a first expansion power module and a second expansion power module. The first expansion power module is detachably installed on one of the two lateral sides of the installation cabinet, and the second expansion power module is detachably installed on the other one of the two lateral sides of the installation cabinet; or the first expansion power module and the second expansion power module are detachably installed on an identical one of the two lateral sides of the installation cabinet.

In an embodiment, the first expansion power module is detachably installed on a front of one of the two lateral sides of the installation cabinet, and the second expansion power module is detachably installed on a front of the other one of the two lateral sides of the installation cabinet; the first expansion power module is detachably installed at a rear of one of the two lateral sides of the installation cabinet, and the second expansion power module is detachably installed at a rear of the other one of the two lateral sides of the installation cabinet; the first expansion power module is detachably installed at a rear of one of the two lateral sides of the installation cabinet, and the second expansion power module is detachably installed at a front of the other one of the two lateral sides of the installation cabinet; or the first expansion power module is detachably installed on a front of one of the two lateral sides of the installation cabinet, and the second expansion power module is detachably installed on a rear of the same one of the two lateral sides of the installation cabinet.

In an embodiment, the power equipment further includes a first set of expansion interfaces and a second set of expansion interfaces. The first set of expansion interface and the first expansion power module are correspondingly arranged on an identical one of the two lateral sides of the installation cabinet, and the second set of expansion interface and the second expansion power module are correspondingly arranged on an identical one of the two lateral sides of the installation cabinet.

In accordance with an aspect of the present disclosure, an assembling method of a power equipment is provided and includes a step S1: disposing a plurality of power modules in an array on a top of an installation cabinet, wherein the plurality of power modules are electrically connected to the installation cabinet, and the plurality of power modules and the installation cabinet are assembled to form a main body; a step S2: transporting the main body and an expansion power module to an installation site, respectively; a step S3, detachably installing the expansion power module on one lateral side of the installation cabinet; and a step S4: electrically connecting the expansion power module to the installation cabinet.

In an embodiment, the expansion power module is detachably installed on the lateral side of the installation cabinet through an installation bracket.

In an embodiment, expansion cables are reserved in the installation cabinet, and electrically connect the expansion power module and the installation cabinet through a set of expansion interfaces.

In an embodiment, the set of expansion interfaces is disposed on one of the two lateral sides of the installation cabinet.

In an embodiment, the set of expansion interfaces is sealed and blocked before the expansion power module is installed.

In an embodiment, one end of the expansion cables passes through the set of expansion interfaces, and is electrically connected to the expansion power module.

The beneficial effect of the present disclosure is that the embodiments of the present invention provide a power equipment and an assembling method thereof. The expansion power module can be detachably installed on the outside of the main body through the installation bracket to achieve the effect of increasing the total output power. The plurality of power modules and the installation cabinet form the first main body for transportation, and the expansion power module forms the second main body for transportation. It helps to improve the transportation efficiency of the power equipment, save the transportation resources, and further achieve the purpose of expanding the output power at installation site.

### BRIEF DESCRIPTION OF THE DRAWINGS

The above contents of the present disclosure will become more readily apparent to those ordinarily skilled in the art after reviewing the following detailed description and accompanying drawings, in which:

FIG. 1 is a perspective view illustrating a power equipment according to a first embodiment of the present disclosure;

FIG. 2 is a structural exploded view illustrating the power equipment of FIG. 1, and the cables in the installation cabinet are hidden;

FIG. 3 is a perspective view illustrating the installation bracket of the power equipment of FIG. 1;

FIG. 4 is a perspective view illustrating the installation cabinet of the power equipment of FIG. 1;

FIG. 5 is a perspective view illustrating the installation cabinet of FIG. 4, wherein the top of the installation cabinet, the front side panel, the cables and the expansion cables are hidden;

FIG. 6 is a perspective view illustrating the DC bus bars in the power equipment of FIG. 5;

FIG. 7 is a perspective view illustrating the AC bus bars in the power equipment of FIG. 5;

FIG. 8 is a front view illustrating a power equipment according to a second embodiment of the present disclosure, and the cables and the expansion cables are hidden;

FIG. 9 is a perspective view illustrating a power equipment according to a third embodiment of the present disclosure, and the cables and the expansion cables are hidden;

FIG. 10 is a structural exploded view illustrating the power equipment of FIG. 9, and the cables and the expansion cables in the installation cabinet are hidden;

FIG. 11 is a perspective view illustrating the installation bracket of the power equipment of FIG. 9;

FIG. 12 is a front view illustrating a power equipment according to a fourth embodiment of the present disclosure, and the cables and the expansion cables are hidden; and

FIG. 13 is s a flow chart showing steps of an assembling method of a power equipment according to an embodiment of the present disclosure.

### DETAILED DESCRIPTION

The present disclosure will now be described more specifically with reference to the following embodiments. It is to be noted that the following descriptions of embodiments of this disclosure are presented herein for purpose of illustration and description only. It is not intended to be exhaustive or to be limited to the precise form disclosed. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed. Further, spatially relative terms, such as “upper,” “lower,” “left,” “right” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When an element is referred to as being “connected,” or “coupled,” to another element, it can be directly connected or coupled to the other element or intervening elements may be present. Although the wide numerical ranges and parameters of the present disclosure are approximations, numerical values are set forth in the specific examples as precisely as possible. In addition, although the “first,” “second,” “third,” and the like terms in the claims be used to describe the various elements can be appreciated, these elements should not be limited by these terms, and these elements are described in the respective embodiments are used to express the different reference numerals, these terms are only used to distinguish one element from another element. For example, a first element could be termed a second element, and, similarly, a second element could be termed a first element, without departing from the scope of example embodiments. Besides, “and/or” and the like may be used herein for including any or all combinations of one or more of the associated listed items. Alternatively, the word “about” means within an acceptable standard error of ordinary skill in the art-recognized average. In addition to the operation/working examples, or unless otherwise specifically stated otherwise, in all cases, all of the numerical ranges, amounts, values and percentages, such as the number for the herein disclosed materials, time duration, temperature, operating conditions, the ratio of the amount, and the like, should be understood as the word “approximately” or “substantially” decorator. Accordingly, unless otherwise indicated, the numerical parameters of the present invention and scope of the appended patent proposed is to follow changes in the desired approximations. At least, the number of significant digits for each numerical parameter should at least be reported and explained by conventional rounding technique is applied. Herein, it can be expressed as a range between from one endpoint to the other or both endpoints. Unless otherwise specified, all ranges disclosed herein are inclusive.

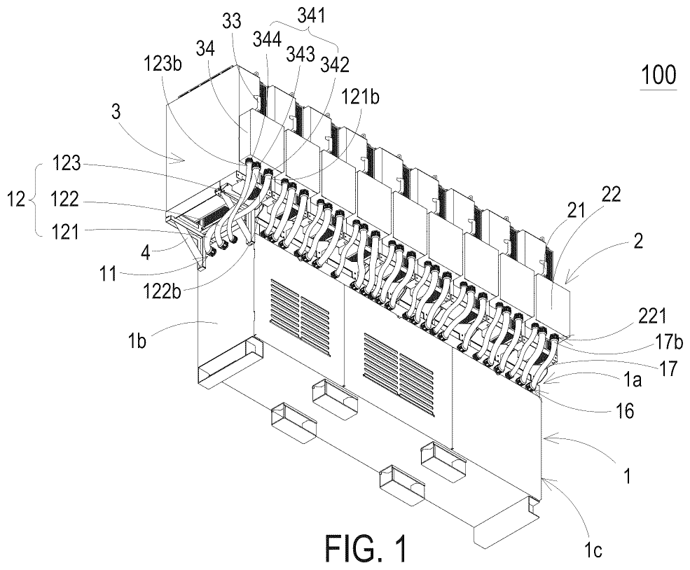

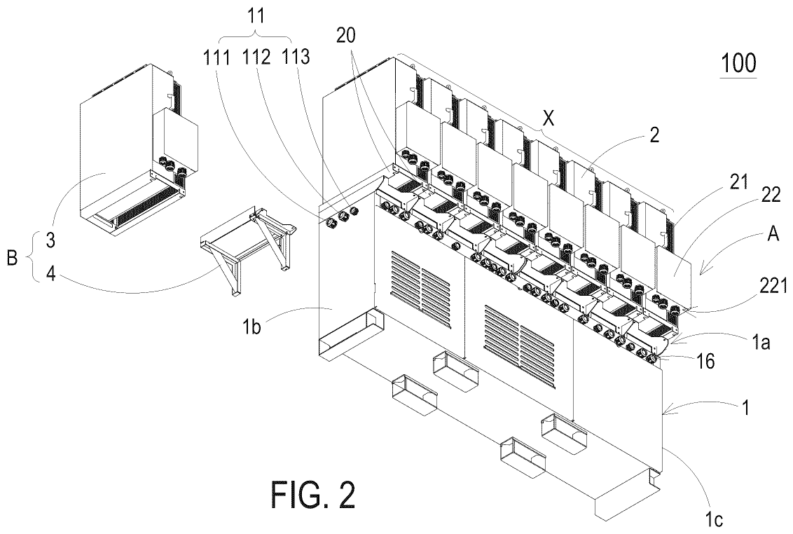

FIG. 1 is a perspective view illustrating a power equipment according to a first embodiment of the present disclosure. FIG. 2 is a structural exploded view illustrating the power equipment of FIG. 1, and the cables in the installation cabinet are hidden. As shown in FIG. 1 and FIG. 2, in the embodiment, the power equipment 100 includes an installation cabinet 1, a plurality of power modules 2 and at least one expansion power module 3. The installation cabinet 1 includes a top 1a, a first lateral side 1b and a second lateral side 1c. The first lateral side 1b and the second lateral side 1c are located at two opposite sides of the installation cabinet 1, respectively. The plurality of power modules 2 are electrically connected to the installation cabinet 1 and arranged in an array on the top 1a of the installation cabinet 1. Preferably but not exclusively, the plurality of power modules 2 and the installation cabinet 1 are assembled as a first main body A. The at least one expansion power module 3 is detachably disposed on one of the first lateral side 1b and the second lateral side 1c of the installation cabinet 1 and electrically connected to the installation cabinet 1. In the embodiment, the expansion power module 3 is detachably installed on the first lateral side 1b of the installation cabinet 1 as an example, but the present disclosure is not limited thereto. By detachably installing the expansion power module 3 on the outside of the first main body A, the effect of increasing the total output power is achieved.

In the embodiment, the plurality of power modules 2 are fixed to the top 1a of the installation cabinet 1 through a plurality of brackets 20. The plurality of brackets 20 are fixed on the top 1a of the installation cabinet 1 in an array. Each power module 2 is installed on a guiding rail (not shown) of the corresponding bracket 20 and fixed by bolts (not shown), but the present disclosure is not limited thereto.

In the embodiment, the installation cabinet 1 and the plurality of power modules 2 are assembled as the first main body A for transportation, and the expansion power module 3 is served as a second main body B for transportation. A general standard container can accommodate two first main bodies A, and the second main body B and the first main body A are separately transported to an installation site and assembled at the installation site. Thereby, transportation efficiency of the power equipment 100 is improved and the transportation resources are saved. It also achieves the purpose of expanding the output power at the installation site.

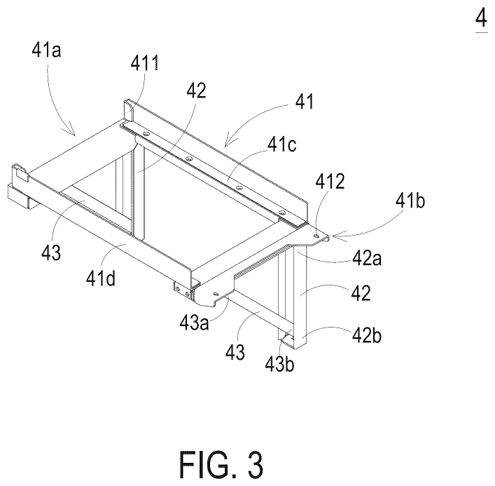

FIG. 3 is a perspective view illustrating the installation bracket of the power equipment of FIG. 1. As shown in FIG. 1 to FIG. 3, in the embodiment, the power equipment 100 further includes an installation bracket 4. The expansion power module 3 is installed on the first main body A through the installation bracket 4. In the embodiment, the installation bracket 4 is regarded as the second main body B for transportation. Preferably but not exclusively, the installation bracket 4 is detachably disposed on one of the first lateral side 1b and the second lateral side 1c of the installation cabinet 1. In the embodiment, the installation bracket 4 is detachably disposed on the first lateral side 1b of the installation cabinet 1 as an example, but the present disclosure is not limited thereto. The installation bracket 4 includes a guiding rail 41. The guiding rail 41 includes a first end 41a, a second end 41b, a slot 411 and at least one fixing hole 412. The first end 41a and the second end 41b are two opposite ends of the guiding rail 41. The slot 411 of the guiding rail 41 is disposed at the first end 41a. The at least one fixing hole 412 of the guiding rail 41 is disposed at the second end 41b. The expansion power module 3 is slid from the second end 41b of the guiding rail 41 toward the first end 41a, and locked in the slot 411, and then the expansion power module 3 is fixed to the at least one fixing hole 412 through bolts (not shown). With the arrangement of the installation bracket 4, the expansion power module 3 is quickly fixed on the first lateral side 1b of the installation cabinet 1, and the expansion power module 3 and the plurality of power modules 2 are cooperated to form an array.

As shown in FIG. 1 and FIG. 2, in the embodiment, each power module 2 has a handle 21 disposed at a front end thereof for the user to hold the power module 2, thereby improving the assembling convenience. In the embodiment, each power module 2 includes a junction box 22. There is a set of terminals 221 disposed at a bottom of the junction box 22 for electrical connection of the corresponding cables 17. Preferably but not exclusively, the terminal 221 is a cable gland, so that the cable passes through the terminal and is electrically connected to the corresponding power module. In an embodiment, each power module 2 is provided with a heat dissipation channel (not shown) at a rear end thereof, thereby improving heat dissipation performance. In the embodiment, the expansion power module 3 includes a handle 33 disposed at a front end thereof for the user to hold the expansion power module 3 to improve assembling convenience. In the embodiment, the expansion power module 3 includes a junction box 34. There is a set of terminals 341 disposed at a bottom of the junction box 34. The terminals 341 include a DC terminal 342, an AC terminal 343 and a control terminal 344 for electrical connection with the corresponding expansion cable 12. Preferably but not exclusively, the terminal 341 is a cable gland, so that the cable passes through the terminal and is electrically connected to the expansion power module 3. In an embodiment, each expansion power module 3 is provided with a heat dissipation channel (not shown) at a rear end thereof, thereby improving heat dissipation performance.

As shown in FIG. 3, in the embodiment, the installation bracket 4 further includes a fixed arm 42 and a support rod 43. The guiding rail 41 includes a first lateral edge 41c and a second lateral edge 41d opposite to each other. The fixed arm 42 includes a first end 42a and a second end 42b opposite to each other. The first end 42a of the fixed arm 42 is connected to the rear side of the guiding rail 41 and connected to the first lateral edge 41c of the guiding rail 41. The fixed arm 42 is extended in a direction perpendicular to the guiding rail 41. The fixed arm 42 is detachably fixed on the first lateral side 1b of the installation cabinet 1. In an embodiment, the fixed arm 42 is fixed to the first lateral side 1b of the installation cabinet 1 through bolts (not shown), but the present disclosure is not limited thereto. The support rod 43 includes a first end 43a and a second end 43b opposite to each other. The first end 43a of the support rod 43 is connected to the second lateral edge 41d of the guiding rail 41. The second end 43b of the support rod 43 is connected to the second end 42b of the fixed arm 42. By connecting and disposing the guiding rail 41, the fixed arm 42 and the support rod 43, the installation bracket 4 forms a triangular support structure, but it is not limited thereto, thereby improving the stability of the structure and support.

As shown in FIG. 1 and FIG. 2, in the embodiment, the installation cabinet 1 includes a set of expansion interfaces 11 and a plurality of expansion cables 12. The set of expansion interfaces 11 is arranged on one of the first lateral side 1b and the second lateral side 1c of the installation cabinet 1. In the embodiment, the set of expansion interfaces 11 is disposed on the first lateral side 1b of the installation cabinet 1 as an example, so that the set of expansion interfaces 11 and the expansion power module 3 are located on an identical side of the installation cabinet 1, but the present disclosure is not limited thereto. The plurality of expansion cables 12 are reserved in the installation cabinet 1. When the expansion power module 3 is installed on the first lateral side 1 b of the installation cabinet 1, the plurality of expansion cables 12 pass through the set of expansion interfaces 11 and are electrically connected to the expansion power module 3.

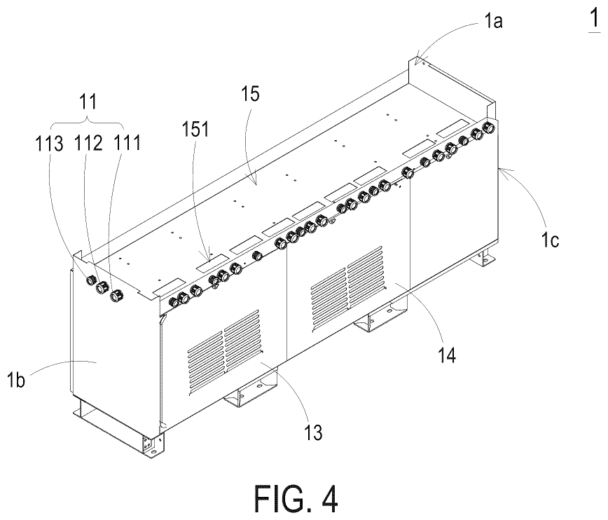

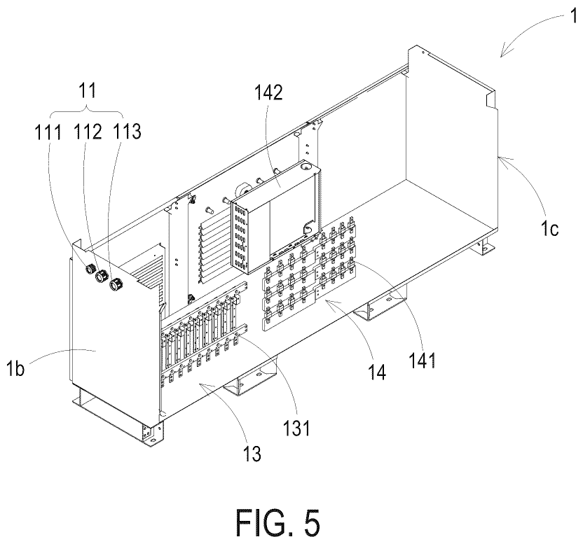

FIG. 4 is a perspective view illustrating the installation cabinet of the power equipment of FIG. 1. FIG. 5 is a perspective view illustrating the installation cabinet of FIG. 4, and the top of the installation cabinet, the front side panel, the cables and the expansion cables are hidden. As shown in FIG. 1 to FIG. 5, in the embodiment, the set of expansion interfaces 11 includes a first expansion interface 111, a second expansion interface 112 and a third expansion interface 113. The installation cabinet 1 includes a DC warehouse 13, an AC warehouse 14 and a wiring warehouse 15. In the embodiment, the DC warehouse 13 is located adjacent to the AC warehouse 14, and the wiring warehouse 15 is in communication with and installed on tops of the DC warehouse 13 and the AC warehouse 14. The plurality of expansion cables 12 include an expansion DC cable 121, an expansion AC cable 122 and an expansion control cable 123.

Preferably but not exclusively, in an embodiment, the first expansion interface 111, the second expansion interface 112 and the third expansion interface 113 are cable glands. In an embodiment, the set of expansion interfaces 11 includes a plurality of sealing covers (not shown). Before the expansion power module 3 is installed in the installation cabinet 1, the plurality of sealing covers are pre-blocked on the first expansion interface 111, the second expansion interface 112 and the third expansion interface 113, so as to achieve the waterproof and dustproof effects during transportation. During the assembling process of the expansion power module 3, the sealing covers are removed from the first expansion interface 111, the second expansion interface 112 and the third expansion interface 113. The expansion DC cable 121, the expansion AC cable 122 and the expansion control cable 123 pass through the first expansion interface 111, the second expansion interface 112 and the third expansion interface 113 respectively, and are electrically connected to the expansion power module 3.

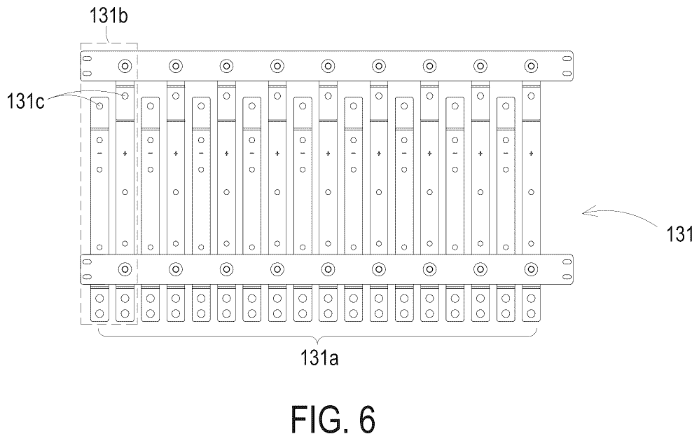

FIG. 6 is a perspective view illustrating the DC bus bars in the power equipment of FIG. 5. As shown in FIG. 1 to FIG. 6, in the embodiment, plural sets of DC bus bars 131 are provided in the DC warehouse 13. For example, nine sets are provided. The plural sets of DC bus bars 131 are arranged adjacent to each other to form a DC bus bar array 131 a. One side of the DC bus bar array 131a faces the first lateral side 1b, and another side of the DC bus bar array 131a faces the second lateral side 1c. In the embodiment, one set of DC bus bars 131 closest to the first lateral side 1b of the installation cabinet 1 is corresponding to the expansion DC bus bar 131b. The first end (not shown) of one set of expansion DC cables 121 is electrically connected to the expansion DC terminals 131c of the set of expansion DC bus bars 131b, and the set of expansion DC cables 121 is led into the wiring warehouse 15 through the hole 151 from bottom to top, and the second end 121b of the set of expansion DC cables 121 is reserved in the wiring warehouse 15. When the expansion power module 3 is installed on the first lateral side 1b of the installation cabinet 1, the second end 121b of the set of expansion DC cables 121 passes through the first expansion interface 111 of the set of expansion interfaces 11, passes through the DC terminal 342 of the terminal 341 of the junction box 34 of the expansion power module 3, and is electrically connected to the DC side of the expansion power module 3. That is shown in FIG. 1. In that, the transmission of direct current is achieved. By disposing the expansion DC bus bars 131b adjacent to the first lateral side 1b, the wiring path of the expansion DC cable 121 is shortened.

In the embodiment, the DC terminals of the remaining DC bus bars 131 are electrically connected to the first ends (not shown) of the corresponding cables 17.

In another embodiment, the expansion power modules are installed on both the first lateral side 1b and the second lateral side 1c of the installation cabinet 1. There are ten sets of DC bus bars 131 disposed in the DC warehouse. The ten sets of DC bus bars 131 are arranged adjacent to each other to form a DC bus bar array. One side of the DC bus bar array faces the first lateral side 1b, and another side of the DC bus bar array faces the second lateral side 1c. The set of DC bus bars 131 closest to the first lateral side 1b of the installation cabinet 1 is corresponding to the expansion DC bus bar 131b, and the set of DC bus bars 131 closest to the second lateral side 1c of the installation cabinet 1 is corresponding to another set of expansion DC bus bar (not shown).

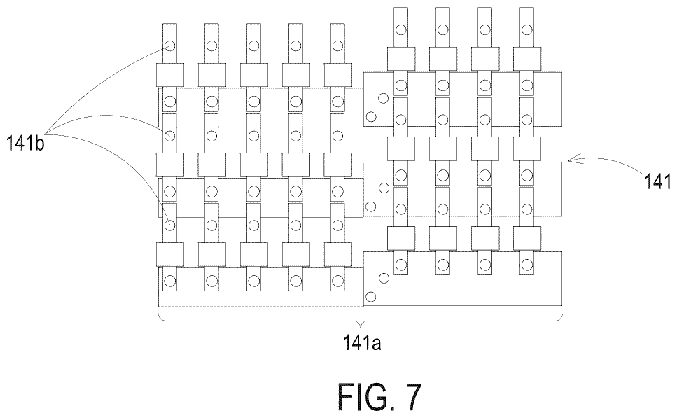

FIG. 7 is a perspective view illustrating the AC bus bars in the power equipment of FIG. 5. As shown in FIG. 1 to FIG. 5 and FIG. 7, in the embodiment, three AC bus bars 141 are provided in the AC warehouse 14 to correspond to three-phase AC power. A plurality of AC terminals are provided on each AC bus bar 141 to form plural sets of AC terminals, for example, nine sets are provided. The plural sets of AC terminals are arranged adjacent to each other to form an AC terminal array 141a. One side of the AC terminal array 141a faces the first lateral side 1b, and another side of the AC terminal array 141a faces the second lateral side 1c. The set of AC terminals closest to the first lateral side 1b of the installation cabinet 1 is corresponding to an expansion AC terminals 141b. The first end (not shown) of the set of expansion AC cables 122 is electrically connected to the set of expansion AC terminals 141b, and the set of expansion AC cables 122 is led into the wiring warehouse 15 from bottom to top through the hole 151, and the second end 122b of the set of expansion AC cables 122 is reserved in wiring warehouse 15. When the expansion power module 3 is installed on the first lateral side 1b of the installation cabinet 1, the second end 122b of the set of expansion AC cables 122 passes through the second expansion interface 112 of the set of expansion interfaces 11, passes through the AC terminal 343 of the terminal 341 of the junction box 34 of the expansion power module 3, and is electrically connected to the AC side of the expansion power module 3. That is shown in FIG. 1. In that, the transmission of alternating current is achieved. By disposing the expansion AC terminal 141b adjacent to the first lateral side 1b, the wiring path of the expansion AC cable 122 is shortened.

In the embodiment, the remaining AC terminals are electrically connected to the first ends (not shown) of the corresponding cables 17.

In another embodiment, the expansion power modules are installed on both the first lateral side 1b and the second lateral side 1c of the installation cabinet 1. There are ten sets of AC terminals disposed in the AC warehouse 14. The ten sets of AC terminals are arranged adjacent to each other to form an AC terminal array. One side of the AC terminal array faces the first lateral side 1b, and another side of the AC terminal array faces the second lateral side 1c. The set of AC terminals closest to the first lateral side 1b of the installation cabinet 1 is corresponding to the expansion AC terminal 141b, and the set of AC terminal closest to the second lateral side 1c of the installation cabinet 1 is corresponding to another set of expansion AC terminal (not shown). In the embodiment, the AC warehouse 14 further includes a control box 142 and a set of expansion control cables 123 disposed therein. The set of expansion control cables 123 includes a first end (not shown) electrically connected to the control box 142 and is led into the wiring warehouse 15 from bottom to top through the hole 151. Moreover, a second end 123b of the set of expansion control cables 123 is reserved in the wiring warehouse 14. When the expansion power module 3 is installed on the first lateral side 1b of the installation cabinet 1, the second end 123b of the set of expansion control cables 123 passes through the third expansion interface 113 of the set of expansion interfaces 11, passes through the control terminal 344 of the terminal 341 of the terminal box 34 of the expansion power module 3, and is electrically connected to a control board of the expansion power module 3. That is shown in FIG. 1. In that, the transmission of signal is achieved.

In an embodiment, the installation cabinet 1 further includes a protection warehouse (not shown). The protection warehouse is disposed between the AC warehouse 14 and the second lateral side 1c, and includes plural sets of circuit breakers (not shown). The plural sets of circuit breakers in the protection warehouse are connected to the AC bus bars 141 in the AC warehouse 14 to protect the circuit and avoid the overload, the short circuit and other situations.

In the embodiment, the plurality of power modules 2 form a first array X and are installed on the top 1a of the installation cabinet 1. The installation cabinet 1 includes plural sets of interfaces 16 and a plurality of cables 17. Each set of interfaces 16 is disposed on a front side of the installation cabinet 1 and corresponding to one power module 2 in the first array X.

The first end (not shown) of each cable 17 is electrically connected to a DC bus bar 132, an AC bus bar 143 or the control box 142, and each cable 17 is led into the wiring warehouse 15 through the hole 151 from bottom to top. The second end 17b of each cable 17 is reserved in the wiring warehouse 15. When the power module 2 is installed on the top 1a of the installation cabinet 1, the second end 17b of each cable 17 passes through the corresponding interface 16, passes through the terminal 221 at the bottom of the corresponding power module 2, and is electrically connected to a DC side, an AC side or a control panel of the corresponding power module 2. In that, the transmission of electric energy and control signals is achieved.

In an embodiment, the plurality of power modules 2 are modular modules and include standard modules (not shown), which is beneficial to rapid manufacturing and production. In an embodiment, the expansion power module 3 includes a standard module (not shown) with functions equivalent to those of the power module 2, and further includes functional modules (not shown). The functional module of the expansion power module 3 has additional functions, and its functional configuration can be customized by customers or adjusted according to the practical requirements to achieve functional diversification.

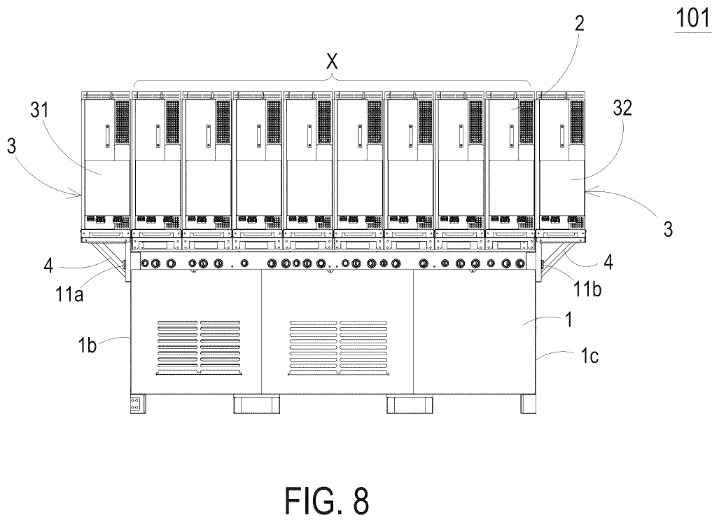

FIG. 8 is a front view illustrating a power equipment according to a second embodiment of the present disclosure, and the cables and the expansion cables are hidden. As shown in FIG. 8, the power equipment 101 includes two expansion power modules 3, which are a first expansion power module 31 and a second expansion power module 32, respectively. In addition, the power equipment 101 includes two installation brackets 4. The first expansion power module 31 is detachably installed on the first lateral side 1b of the installation cabinet 1 through one installation bracket 4, and the second expansion power module 32 is detachably installed on the second lateral side 1c of the installation cabinet 1 through another installation bracket 4. The power equipment 101 includes two sets of expansion interfaces 11, which are a first set of expansion interfaces 11a and a second set of expansion interfaces 11b. The first set of expansion interfaces 11a and the first expansion power module 31 are arranged on the first lateral side 1b of the installation cabinet 1 correspondingly. The second set of expansion interfaces 11b and the second expansion power module 32 are arranged on the second lateral side 1c of the installation cabinet 1 correspondingly. A plurality of expansion cables 121 are reserved in the installation cabinet 1, and electrically connected to the first expansion power module 31 and the second expansion power module 32 through the first set of expansion interfaces 11a and the second set of expansion interfaces 11b, respectively. With the setting of two expansion power modules 3, the output power of the power equipment 101 is increased.

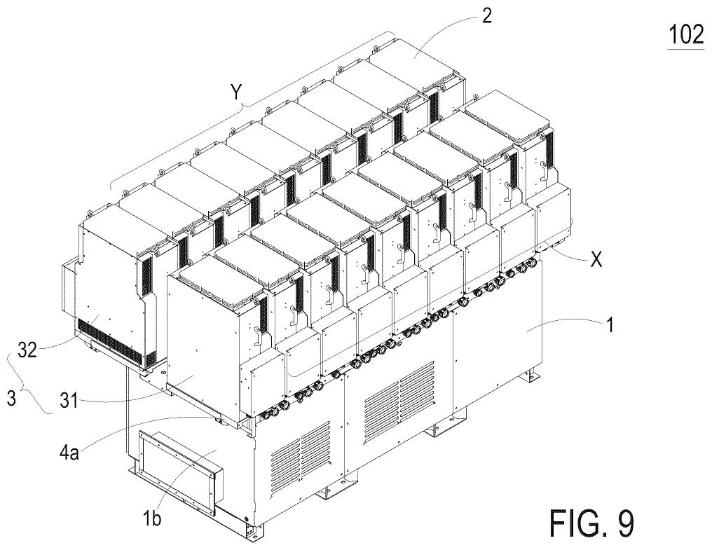

FIG. 9 is a perspective view illustrating a power equipment according to a third embodiment of the present disclosure, and the cables and the expansion cables are hidden. As shown in FIG. 9, in the embodiment, the power equipment 102 includes a plurality of power modules 12. At least part of the plurality of power modules 12 form a first array X and are installed on a front side of the top 1a of the installation cabinet 1. The installation cabinet 1 further includes a plural sets of interfaces 16, and each of the plural sets of interfaces 16 is disposed on a front side of the installation cabinet 11 and spatially corresponding to one of the power modules 2 in the first array X. The remaining plurality of power modules 2 form a second array Y and are installed on a rear side of the top 1a of the installation cabinet 1. The installation cabinet 1 further includes a plural sets of interfaces (not shown), and each of the plural sets of interfaces is disposed on a rear side of the installation cabinet 1 and spatially corresponding to one of the power modules 2 in the second array Y. By arranging the power modules to form the first array X and the second array Y, it allows to install a larger number of power modules 2, thereby increasing the output power. In the embodiment, the size of the first main body A of the power equipment 102 is, for example, but not limited to, a hexahedral structure with a length of 2910 mm, a width of 1974 mm, and a height of 2350 mm.

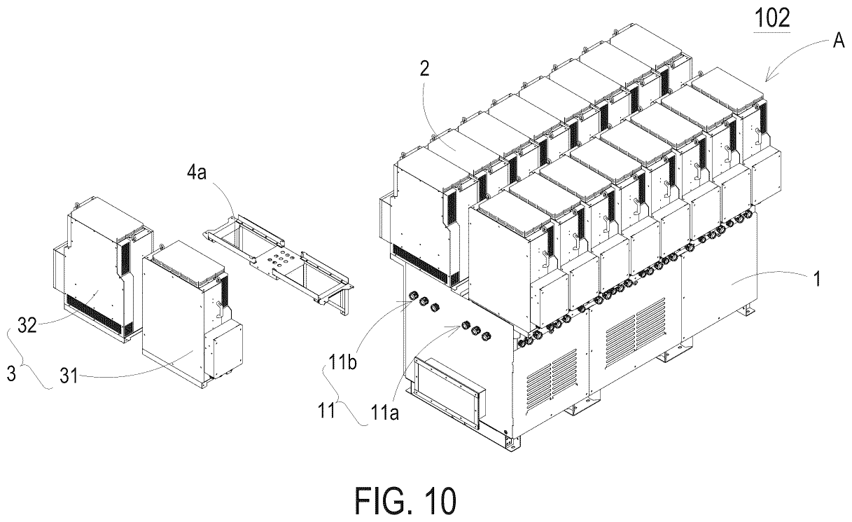

FIG. 10 is a structural exploded view illustrating the power equipment of FIG. 9, and the cables and the expansion cables in the installation cabinet are hidden. As shown in FIG. 9 and FIG. 10, the power equipment 102 includes two expansion power modules 3, which are a first expansion power module 31 and a second expansion power module 32, respectively. The first expansion power module 31 and the second expansion power module 32 are detachably installed on the first lateral side 1b of the installation cabinet 1 through the installation bracket 4a. The power equipment 102 includes two sets of expansion interfaces 11, which are a first set of expansion interfaces 11a and a second set of expansion interfaces 11b. The first set of expansion interfaces 11a and the second set of expansion interface 11b are arranged on the first lateral side 1b of the installation cabinet 1, and corresponding to the first expansion power module 31 and the second expansion power module 32, respectively. A plurality of expansion cables (not shown) are reserved in the installation cabinet 1 and electrically connected to the first expansion power module 31 and the second expansion power module 32 through the first set of expansion interfaces 11a and the second set of expansion interfaces 11b, respectively. With the setting of two expansion power modules 3, the output power of the power equipment 102 is increased.

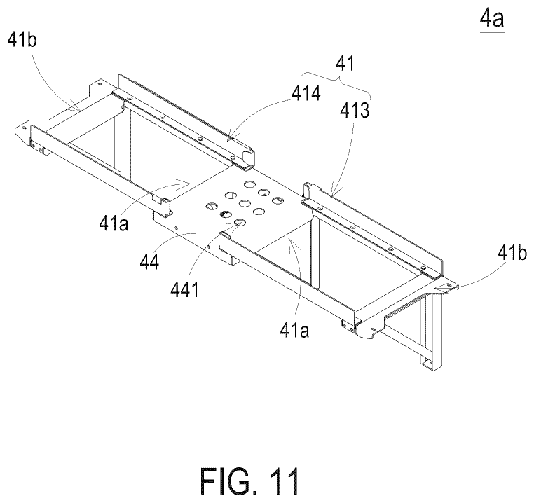

FIG. 11 is a perspective view illustrating the installation bracket of the power equipment of FIG. 9. As shown in FIG. 9 and FIG. 11, the installation bracket 4a of the power equipment 102 is detachably disposed on the first lateral side 1b of the installation cabinet 1, and includes two guiding rails 41, namely a first guiding rail 413 and a second guiding rail 414. The first end 41a of the first guiding rail 413 and the first end 41a of the second guiding rail 414 are connected through a plate 44. The second end 41b of the first guiding rail 413 and the second end 41b of the second guiding rail 414 are respectively extended along the direction away from the plate 44. The first expansion power module 31 is slid and fixed from the second end 41b of the first guiding rail 413 toward the first end 41a. The second expansion power module 32 is slid and fixed from the second end 41b of the second guiding rail 414 toward the first end 41a. With the arrangement of the installation bracket 4a, the two expansion power modules 3 are quickly fixed on the first lateral side 1b of the installation cabinet 1. Moreover, the first expansion power module 31 and the first array X jointly form an array, and the second expansion power module 32 and the second array Y jointly form another array. In an embodiment, the plate 44 further includes a plurality of through holes 441 for drainage. The present disclosure is not limited thereto.

In some embodiments, the power equipment 100 includes two installation brackets 4a detachably disposed on the first lateral side 1b and the second lateral side 1c of the installation cabinet 1. The first expansion power module 31 is detachably disposed on a front of the first lateral side 1b of the installation cabinet 1 through the installation bracket 4a, and the second expansion power module 32 is detachably disposed on a front of the second lateral side 1c of the installation cabinet 1 through the installation bracket 4a. In that, the first expansion power module 31 and the second expansion power module 32 are cooperated with the first array X to form an array. In one embodiment, the first expansion power module 31 is detachably disposed on a rear of the first lateral side 1b of the installation cabinet 1 through the installation bracket 4a, and the second expansion power module 32 is detachably disposed on a rear of the second lateral side 1c of the installation cabinet 1 through the installation bracket 4a. In that, the first expansion power module 31 and the second expansion power module 32 are cooperated with the second array Y to form an array. In one embodiment, the first expansion power module 31 is detachably disposed at a rear of the first lateral side 1b of the installation cabinet 1 through the installation bracket 4a, so that the first expansion power module 31 and the second array Y are cooperated to form an array. The second expansion power module 32 is detachably disposed on a front of the second lateral side 1c of the installation cabinet 1 through the installation bracket 4a, so that the second expansion power module 32 and the first array X are cooperated to form an array. In one embodiment, the first expansion power module 31 is detachably disposed on a front of the first lateral side 1b of the installation cabinet 1 through the installation bracket 4a, so that the first expansion power module 31 and the first array X are cooperated to form an array. The second expansion power module 32 is detachably disposed at a rear of the first lateral side 1b of the installation cabinet 1 through the installation bracket 4a, so that the second expansion power modules 32 and the second array Y are cooperated to form an array.

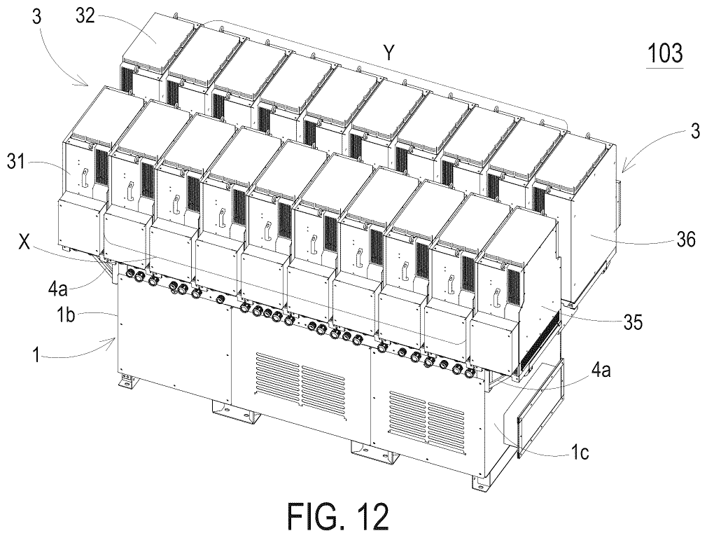

FIG. 12 is a front view illustrating a power equipment according to a fourth embodiment of the present disclosure, and the cables and the expansion cables are hidden. As shown in FIG. 12, in the embodiment, the power equipment 103 includes two installation brackets 4a, which are detachably disposed on the first lateral side 1b and the second lateral side 1c of the installation cabinet 1 respectively. The power equipment 103 includes a plurality of expansion power modules 3, which are a first expansion power module 31, a second expansion power module 32, a third expansion power module 35 and a fourth expansion power module 36. The first expansion power module 31, the second expansion power module 32, the third expansion power module 35 and the fourth expansion power module 36 are respectively detachably disposed on a front of the first lateral side 1b, a rear of the first lateral side 1b, a front of the second lateral side 1c and a rear of the second lateral side 1c of the installation cabinet 1 through the installation brackets 4a. In that, the first expansion power module 31 and the third expansion power module 35 are cooperated with the first array X to form an array, and the second expansion power module 32 and the fourth expansion power module 36 are cooperated with the second array Y to form an array. With the setting of four additional expansion power modules 3, the output power of the power equipment 103 is increased. Certainly, the number and the arrangement of the expansion power modules 3 in the present disclosure are not limited to the above-mentioned embodiments, and can be adjusted or changed according to the practical requirements.

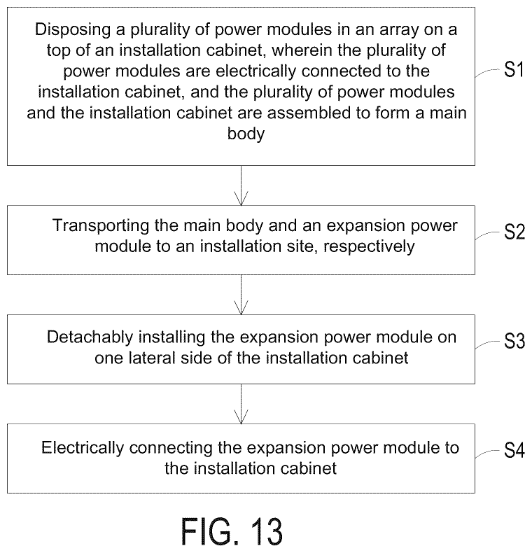

FIG. 13 is s a flow chart showing steps of an assembling method of a power equipment according to an embodiment of the present disclosure. As shown in FIG. 13, the assembling method of the power equipment of the present disclosure includes the following steps. In a step S1, a plurality of power modules 2 are disposed in an array on the top 1a of the installation cabinet 1. The plurality of power modules 2 are electrically connected to the cables 17 in the installation cabinet 1. The plurality of power modules 2 and the installation cabinet 1 are assembled to form a first main body A. In a step S2, at least one expansion power module 3 is served as the second main body B, and the first main body A and the second main body B are transported to an installation site, respectively. In a step S3, the expansion power module 3 is detachably installed on at least one of the first lateral side 1b and the second lateral side 1c of the installation cabinet 1. In a step S4, the expansion power module 3 is electrically connected to the expansion cables 12 reserved in the installation cabinet 1. By detachably installing the expansion power module 3 on the outside of the first main body A, the effect of increasing the total output power is achieved. In the embodiment, a general standard container can accommodate two first main bodies A. Moreover, the second main body B and the first main body A are separately transported to the installation site and then assembled at the installation site. Thereby, the transportation efficiency of the power equipment 100 is improved, the transportation resources are saved, and the purpose of expanding the output power at the installation site is further achieved.

In the embodiment, the expansion power module 3 is detachably installed on the first lateral side 1b or the second lateral side 1c of the installation cabinet 1 through an installation bracket 4 in the step S3.

In the embodiment, the expansion cables 12 reserved are electrically connected to the expansion power module 3 and the installation cabinet 1 through a set of expansion interfaces 11 in the step S4. The set of expansion interfaces 11 is disposed on the first lateral side 1b or the second lateral side 1c of the installation cabinet 1, and corresponding to the expansion power module 3.

In the embodiment, before the expansion power module 3 is installed in the installation cabinet 1, a sealing cover (not shown) is used to seal and block the set of expansion interfaces 11, thereby achieving the waterproof and dustproof effects during transportation.

In the embodiment, the seal cover is removed to open the set of expansion interfaces 11, and the expansion cables 12 reserved pass through the set of expansion interfaces 11, pass through the terminal of the expansion power module 3, and are electrically connected to expansion power module 3.

In summary, the present disclosure provides a power equipment and an assembling method thereof. The expansion power module can be detachably installed on the outside of the main body through the installation bracket to achieve the effect of increasing the total output power. The plurality of power modules and the installation cabinet form the first main body for transportation, and the expansion power module forms the second main body for transportation. It helps to improve the transportation efficiency of the power equipment, save the transportation resources, and further achieve the purpose of expanding the output power at installation site.

It should be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A power equipment, comprising:
an installation cabinet comprising a top and two lateral sides;
a plurality of power modules electrically connected to the installation cabinet and arranged in an array on the top of the installation cabinet; and
at least one expansion power module detachably disposed on one of the two lateral sides of the installation cabinet and electrically connected to the installation cabinet.

2. The power equipment according to claim 1, wherein the installation cabinet and the plurality of power modules are assembled as a first main body for transportation, and the expansion power module is as a second main body for transportation.

3. The power equipment according to claim 1, further comprising an installation bracket detachably disposed on one of the two lateral sides of the installation cabinet, wherein the installation bracket comprises a guiding rail, the guiding rail comprises a slot disposed at a first end thereof and at least one fixing hole disposed at a second end thereof, wherein the expansion power module is slid from the second end of the guiding rail toward the first end, and locked in the slot, and then the expansion power module is fixed to the at least one fixing hole.

4. The power equipment according to claim 1, wherein the installation cabinet comprises a set of expansion interfaces arranged on one of the two lateral sides of the installation cabinet, and the set of expansion interfaces and the expansion power module are located on an identical one of the two lateral sides of the installation cabinet.

5. The power equipment according to claim 1, wherein a plurality of expansion cables are reserved in the installation cabinet for electrically connecting the expansion power module.

6. The power equipment according to claim 4, wherein the set of expansion interfaces comprises a first expansion interface, a second expansion interface and a third expansion interface; and the installation cabinet comprises a DC warehouse, an AC warehouse and a wiring warehouse, wherein the DC warehouse is located adjacent to the AC warehouse, and the wiring warehouse is in communication with and installed on tops of the DC warehouse and the AC warehouse.

7. The power equipment according to claim 6, wherein the DC warehouse comprises:
a set of expansion DC bus bars disposed therein; and
a set of expansion DC cables disposed therein, wherein the set of expansion DC cables includes a first end electrically connected to the set of expansion DC bus bars and a second end reserved in the wiring warehouse,
wherein the second end of the set of expansion DC cables passes through the first expansion interface of the set of expansion interfaces and is electrically connected to a DC side of the expansion power module.

8. The power equipment according to claim 6, wherein the AC warehouse comprises:
a set of expansion AC terminals disposed therein; and
a set of expansion AC cables disposed therein, wherein the set of expansion AC cables includes a first end electrically connected to the set of expansion AC terminals, and a second end reserved in the wiring warehouse,
wherein the second end of the set of expansion AC cables passes through the second expansion interface of the set of expansion interfaces and is electrically connected to a AC side of the expansion power module.

9. The power equipment according to claim 6, wherein the AC warehouse comprises:
a control box disposed therein; and
a set of expansion control cables disposed therein, wherein the set of expansion control cables includes a first end electrically connected to the control box, and a second end reserved in the wiring warehouse;
wherein the second end of the set of expansion control cables passes through the third expansion interface of the set of expansion interfaces and is electrically connected to a control board of the expansion power module.

10. The power equipment according to claim 1, wherein the plurality of power modules form a first array and are installed on the top of the installation cabinet, wherein the installation cabinet further comprises a plural sets of interfaces, and each of the plural sets of interfaces is disposed on a front side of the installation cabinet and spatially corresponding to one of the power modules in the first array.

11. The power equipment according to claim 1, wherein at least part of the plurality of power modules form a first array and are installed on a front side of the top of the installation cabinet, wherein the installation cabinet comprises a plural sets of interfaces, and each of the plural sets of interfaces is disposed on a front side of the installation cabinet and spatially corresponding to one of the power modules in the first array; and
at least part of the remaining plurality of power modules form a second array and are installed on a rear side of the top of the installation cabinet, wherein the installation cabinet further comprises a plural sets of interfaces, and each of the plural sets of interfaces is disposed on a rear side of the installation cabinet and spatially corresponding to one of the power modules in the second array.

12. The power equipment according to claim 1, further comprising a first expansion power module and a second expansion power module;
wherein the first expansion power module is detachably installed on one of the two lateral sides of the installation cabinet, and the second expansion power module is detachably installed on the other one of the two lateral sides of the installation cabinet; or
the first expansion power module and the second expansion power module are detachably installed on an identical one of the two lateral sides of the installation cabinet.

13. The power equipment according to claim 12, wherein
the first expansion power module is detachably installed on a front of one of the two lateral sides of the installation cabinet, and the second expansion power module is detachably installed on a front of the other one of the two lateral sides of the installation cabinet;
the first expansion power module is detachably installed at a rear of one of the two lateral sides of the installation cabinet, and the second expansion power module is detachably installed at a rear of the other one of the two lateral sides of the installation cabinet;
the first expansion power module is detachably installed at a rear of one of the two lateral sides of the installation cabinet, and the second expansion power module is detachably installed at a front of the other one of the two lateral sides of the installation cabinet; or
the first expansion power module is detachably installed on a front of one of the two lateral sides of the installation cabinet, and the second expansion power module is detachably installed on a rear of the same one of the two lateral sides of the installation cabinet.

14. The power equipment according to claim 12, further comprising a first set of expansion interfaces and a second set of expansion interfaces, wherein the first set of expansion interface and the first expansion power module are correspondingly arranged on an identical one of the two lateral sides of the installation cabinet, and the second set of expansion interface and the second expansion power module are correspondingly arranged on an identical one of the two lateral sides of the installation cabinet.

15. An assembling method of a power equipment, comprising:
a step S1: disposing a plurality of power modules in an array on a top of an installation cabinet, wherein the plurality of power modules are electrically connected to the installation cabinet, and the plurality of power modules and the installation cabinet are assembled to form a main body;
a step S2: transporting the main body and an expansion power module to an installation site, respectively;
a step S3, detachably installing the expansion power module on one lateral side of the installation cabinet; and
a step S4: electrically connecting the expansion power module to the installation cabinet.

16. The assembling method according to claim 15, wherein the expansion power module is detachably installed on the lateral side of the installation cabinet through an installation bracket.

17. The assembling method according to claim 15, wherein expansion cables are reserved in the installation cabinet, and electrically connect the expansion power module and the installation cabinet through a set of expansion interfaces.

18. The assembling method according to claim 17, wherein the set of expansion interfaces is disposed on one of the two lateral sides of the installation cabinet.

19. The assembling method according to claim 18, wherein the set of expansion interfaces is sealed and blocked before the expansion power module is installed.

20. The assembling method of claim 18, wherein one end of the expansion cables passes through the set of expansion interfaces, and is electrically connected to the expansion power module.
